(19) United States
(12) Patent Application Publication
(10) Pub. No.: US 2025/0118681 A1
(43) Pub. Date: Apr. 10, 2025

(54) SEMICONDUCTOR PACKAGE, ELECTRONIC DEVICE INCLUDING THE SEMICONDUCTOR PACKAGE AND METHOD OF MANUFACTURING THE ELECTRONIC DEVICE

(71) Applicant: Samsung Electronics Co., Ltd., Suwon-si (KR)

(72) Inventor: Seungmin Kim, Suwon-si (KR)

(21) Appl. No.: 18/906,004

(22) Filed: Oct. 3, 2024

(30) Foreign Application Priority Data
Oct. 5, 2023 (KR) 10-2023-0132503
Nov. 16, 2023 (KR) 10-2023-0159472

(51) Int. Cl. H01L 23/544; H01L 21/56; H01L 23/00; H01L 23/31; H01L 23/498; H01L 23/552; H05K 1/18

(52) U.S. Cl. CPC H01L 23/544; H01L 23/3128; H01L 23/49822; H01L 23/49838; H01L 23/552; H01L 21/56; H01L 24/32; H01L 24/48; H01L 24/73; H01L 24/96; H01L 24/97; H01L 2223/54426; H01L 2224/32225; H01L 2224/48225; H01L 2224/73265; H01L 2224/96; H01L 2224/97; H01L 2924/1815; H05K 1/181

(57) ABSTRACT

A semiconductor package includes a package substrate having substrate pads disposed in a middle region and a reference mark disposed at a first corner portion adjacent to a first corner within an edge region surrounding the middle region on a lower surface of the package substrate; at least one semiconductor chip mounted on an upper surface of the package substrate; a sealing member covering the at least one semiconductor chip on the package substrate; an electromagnetic shielding member covering a side surface of the package substrate and an upper surface and a side surface of the sealing member; and at least one barrier protruding downwards from the lower surface of the package substrate and is disposed between the first corner and the reference mark.

### PRIORITY STATEMENT

This application claims priority under 35 U.S.C. § 119 to Korean Patent Application Nos. 10-2023-0132503, filed on Oct. 5, 2023 and 10-2023-0159472, filed Nov. 16, 2023 in the Korean Intellectual Property Office (KIPO), the contents of which are herein incorporated by reference in their entirety.

### BACKGROUND

### 1. Field

Example embodiments relate to a semiconductor package, an electronic device including the semiconductor package and a method of manufacturing the electronic device. More particularly, example embodiments relate to a semiconductor package having an electromagnetic wave shielding layer, an electronic device including the same, and a method of manufacturing the electronic device.

### 2. Description of the Related Art

In order to shield electromagnetic waves emitted from a semiconductor package, an electromagnetic wave shield (EMI shield) layer may be formed on a side surface and a top surface of the semiconductor package. Before forming the electromagnetic wave shielding layer, a protective tape may be attached to a lower surface of the semiconductor package by a lamination method. However, when forming the electromagnetic wave shielding layer, the protective tape may be lifted at the edge portion, and a portion of the electromagnetic wave shielding layer may penetrate and cover an alignment mark on the lower surface of the semiconductor package, resulting in a recognition defect.

### SUMMARY

Example embodiments provide a semiconductor package that is able to prevent alignment mark recognition defects caused by electromagnetic wave shielding materials.

Example embodiments provide a method of manufacturing the electronic device.

According to example embodiments, a semiconductor package includes a package substrate having substrate pads disposed in a middle region and a reference mark disposed at a first corner portion adjacent to a first corner within an edge region surrounding the middle region on a lower surface of the package substrate; at least one semiconductor chip mounted on an upper surface of the package substrate; a sealing member covering the at least one semiconductor chip on the package substrate; an electromagnetic shielding member covering a side surface of the package substrate and an upper surface and a side surface of the sealing member; and at least one barrier protruding downwards from the lower surface of the package substrate and is disposed between the first corner and the reference mark.

According to example embodiments, a semiconductor package includes a package substrate including a middle region and an edge region surrounding the middle region, the package substrate including a reference mark that is disposed at a first corner portion adjacent to a first corner within the edge region on a lower surface of the package substrate to provide a reference for orientation or positioning during a manufacturing process; at least one semiconductor chip mounted on an upper surface of the package substrate; a sealing member covering the at least one semiconductor chip on the package substrate; an electromagnetic shielding member covering a side surface of the package substrate and an upper surface and a side surface of the sealing member; and at least one barrier protruding downwards on the lower surface of the package substrate and extending between the first corner and the reference mark to surround at least a portion of the reference mark.

According to example embodiments, an electronic device includes a main board; a semiconductor package disposed on the main board and mounted via a plurality of conductive connection members; and an electromagnetic shielding member covering an upper surface and a side surface of the semiconductor package. The semiconductor package includes a package substrate having a middle region and an edge region surrounding the middle region, the package substrate including a reference mark that is disposed at a first corner portion adjacent to a first corner within the edge region on a lower surface of the package substrate; and at least one barrier protruding downwards on the lower surface of the package substrate and disposed between the first corner and the reference mark.

According to example embodiments, a semiconductor package may include a unit package and an electromagnetic shielding member covering an upper surface and a side surface of the unit package. The unit package may include a package substrate having lower substrate pads disposed in a middle region on a lower surface and a reference mark disposed at a first corner portion adjacent to a first corner within an edge region surrounding the middle region, and at least one barrier disposed on the lower surface of the package substrate between the reference mark and the first corner.

When the electromagnetic shielding member is formed, a backspill defect where a portion of the electromagnetic shielding material penetrates onto the lower surface of the unit package to move to the reference mark may occur. At this time, the at least one barrier may block the portion of the electromagnetic shielding material from moving to the reference mark.

Accordingly, the position and inspection position of the package may be automatically corrected by checking the reference mark during a manufacturing process such as a package mounting process after the formation process of the electromagnetic shielding member.

### BRIEF DESCRIPTION OF THE DRAWINGS

Example embodiments will be more clearly understood from the following detailed description taken in conjunction with the accompanying drawings. FIGS. 1 to 17 represent non-limiting, example embodiments as described herein.

FIG. 1 is a cross-sectional view illustrating an electronic device in accordance with example embodiments.

FIG. 2 is an enlarged cross-sectional view illustrating portion ‘A’ in FIG. 1.

FIG. 3 is a bottom view illustrating a plurality of lower substrate pads and a reference mark on a bottom surface of a semiconductor package in FIG. 1.

FIG. 4 is an enlarged bottom view illustrating portion ‘B’ in FIG. 3.

FIGS. 5 to 15 are views illustrating a method of manufacturing an electronic device in accordance with example embodiments.

FIG. 16 is an enlarged cross-sectional view illustrating the electromagnetic shielding member that has penetrated onto the lower surface of the semiconductor package in portion ‘A’ of FIG. 1.

FIG. 17 is a bottom view illustrating the lower surface of the semiconductor package of FIG. 16.

### DETAILED DESCRIPTION OF EXAMPLE EMBODIMENTS

Hereinafter, example embodiments will be explained in detail with reference to the accompanying drawings.

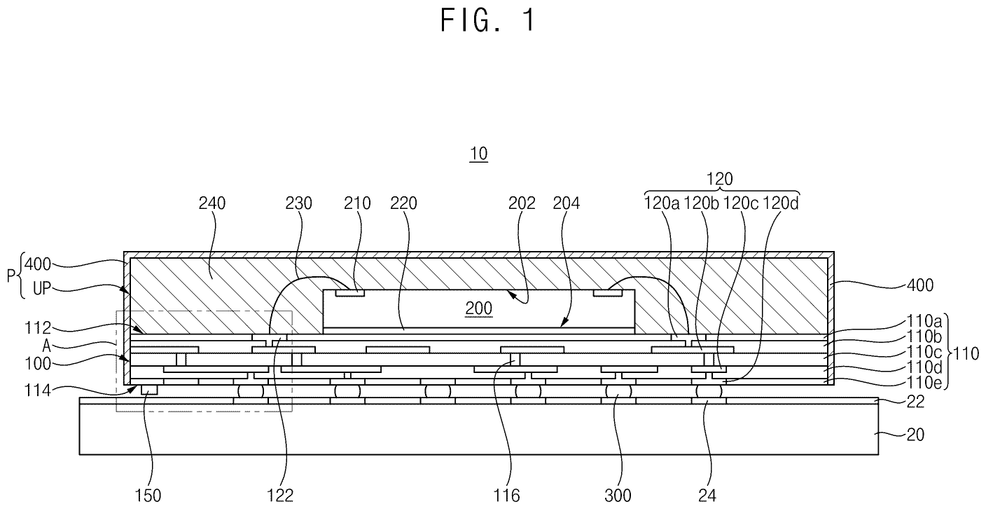

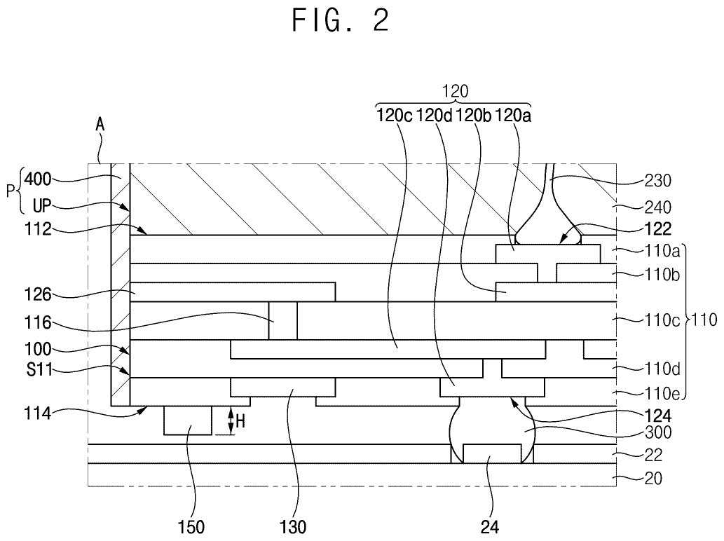

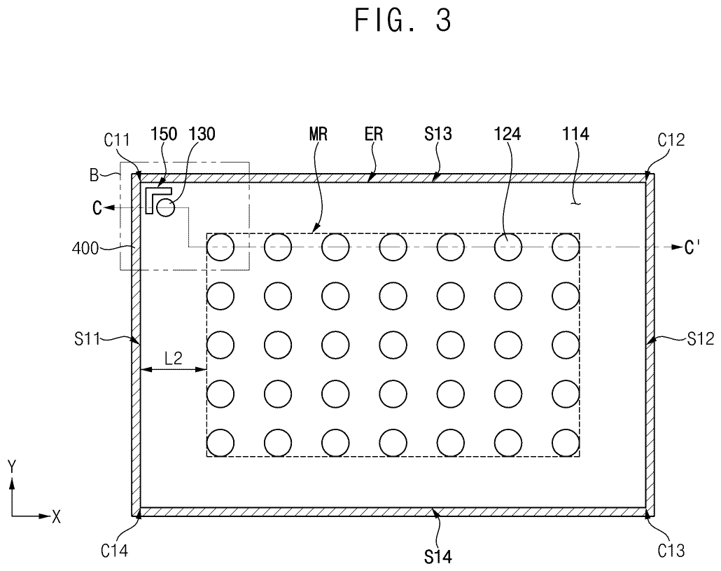

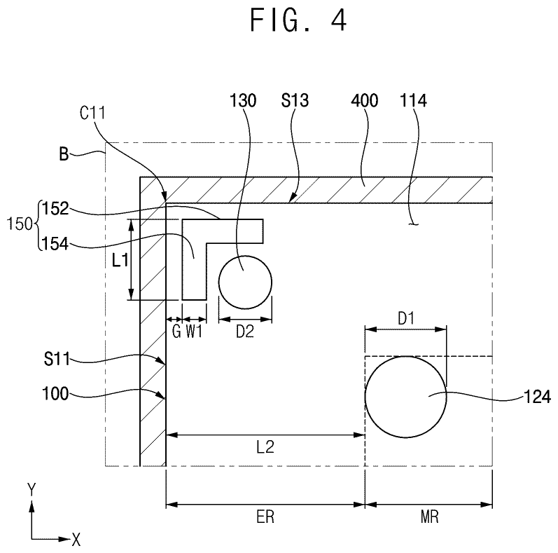

FIG. 1 is a cross-sectional view illustrating an electronic device in accordance with example embodiments. FIG. 2 is an enlarged cross-sectional view illustrating portion ‘A’ in FIG. 1. FIG. 3 is a bottom view illustrating a plurality of lower substrate pads and a reference mark on a bottom surface of a semiconductor package in FIG. 1. FIG. 4 is an enlarged bottom view illustrating portion ‘B′ in FIG. 3. FIG. 1 includes a cross-sectional portion taken along the line C-C’ in FIG. 3.

Referring to FIGS. 1 to 4, an electronic device 10 may include a main board 20, a semiconductor package P and a plurality of conductive connection members 300. The semiconductor package P may include a unit package UP and an electromagnetic shielding member 400 covering an upper surface and a side surface of the unit package UP.

In example embodiments, the main board 20 may be a multilayer circuit board having an upper surface and a lower surface opposite to each other. For example, the main board 20 may be a printed circuit board (PCB). The printed circuit board may be a multilayer circuit board having vias and various circuits therein.

The main board 20 may include a plurality of pads 24 on the upper surface thereof and a protective layer 22 having openings that expose the plurality of pads 24 respectively. The plurality of pads 24 may be electrically connected to various circuit wires formed in the main board 20. The plurality of pads 24 may include a plurality of signal pads and a plurality of ground pads. The ground pads may be electrically connected to a separate ground circuit (not shown) formed in the main board 20. As used herein, components described as being “electrically connected” are configured such that an electrical signal can be transferred from one component to the other (although such electrical signal may be attenuated in strength as it is transferred and may be selectively transferred).

In example embodiments, the unit package UP may include a package substrate 100, at least one semiconductor chip 200 mounted on the package substrate 100, and a sealing member 240 covering the at least one semiconductor chip 200 on the package substrate 100.

As illustrated in FIG. 2, the package substrate 100 may be a multilayer circuit substrate having an upper surface 112 and a lower surface 114 opposite to each other. The package substrate 100 may include or may be a printed circuit board (PCB), a flexible substrate, a tape substrate, etc. The package substrate 100 may include a plurality of stacked insulating layers 110 and wirings 120a, 120b, 120c and 120d respectively provided in the insulating layers. Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

For example, the package substrate 100 may include first to fifth insulating layers 110a, 110b, 110c, 110d, 110e sequentially stacked. The first insulating layer 110a may be an upper cover insulating layer, the second insulating layer 110b may be an upper insulating layer, the third insulating layer 110c may be a core layer, the fourth insulating layer 110d may be a lower insulating layer, and the fifth insulating layer 110e may be a lower cover insulating layer.

The third insulating layer 110c as the core layer may include a non-conductive material layer. The third insulating layer 110c may include a reinforcing polymer or the like. The third insulating layer 110c may serve as a boundary layer dividing an upper portion and a lower portion of the package substrate 100.

A second wiring 120b may be formed on an upper surface of the third insulating layer 110c. The second insulating layer 110b may be formed on the upper surface of the third insulating layer 110c to cover the second wiring 120b. A first wiring 120a may be formed on an upper surface of the second insulating layer 110b, and may be electrically connected to the second wiring 120b through an opening formed in the second insulating layer 110b.

A third wiring 120c may be formed on a lower surface of the third insulating layer 110c. The fourth insulating layer 110d may be formed on the lower surface of the third insulating layer 110c to cover the third wiring 120c. A fourth wiring 120d may be formed on a lower surface of the fourth insulating layer 110d, and may be electrically connected to the third wiring 120c through an opening formed in the fourth insulating layer 110d.

The first to fourth wirings 120a, 120b, 120c and 120d may be referred to as a first to fourth circuit layers stacked (e.g., sequentially arranged) in a thickness direction from the upper surface 112 to the lower surface 114 of the package substrate 100. For example, the wiring may include metal materials such as copper, aluminum, etc. It will be understood that the arrangements and numbers of the insulating layers and the wirings are illustrative and the inventive concept is not limited thereto.

A conductive through via 116 may penetrate the third insulating layer 110c as the core layer and electrically connect the second wiring 120b and the third wiring 120c. The first wiring 120a may be exposed from the upper surface 112 of the package substrate 100. The fourth wiring 120d may be exposed from the lower surface 114 of the package substrate 100.

The first insulating layer 110a as an upper protective layer may be formed on the upper surface 112 of the package substrate 100, and may expose at least a portion of the first wiring 120a. For example, the first insulating layer 110a may be formed at a top of the package substrate 100, and an upper surface of the first insulating layer 110a may form the upper surface 112 of the package substrate 100. The exposed portion of the first wiring 120a may be provided as an upper substrate pad 122. The fifth insulating layer 110e as a lower protective layer may be provided on the lower surface 114 of the package substrate 100, and may expose at least a portion of the fourth wiring 120d. For example, the fifth insulating layer 110e may be formed at a bottom of the package substrate 100, and a lower surface of the fifth insulting layer 110e may form the lower surface 114 of the package substrate 100. The exposed portion of the fourth wiring 120d may be provided as a lower substrate pad 124. The upper insulating layer 110a and the lower insulating layer 110e may separate/protect the circuit patterns of the package substrate 100 from the external environment to prevent contamination and electrically insulate the wirings of the circuit patterns from each other. For example, the upper insulating layer and the lower insulating layer may include a photosensitive resin such as photo epoxy or a photosensitive polymer such as photo solder resist (PSR).

As illustrated in FIG. 3, the package substrate 100 may include a first side portion S11 and a second side portion S22 extending in a direction parallel to a second direction (Y direction) and opposite each other, and a third side portion S13 and a fourth side portion S14 extending in a direction parallel to a first direction (X direction) perpendicular to the second direction (Y direction) and opposite each other. For example, the first to fourth side portions S11, S12, S13, and S14 may be respective side surfaces of the package substrate 100. The package substrate 100 may include a middle region MR and an edge region ER surrounding the middle region MR. The middle region MR may be spaced apart from the first side portion S11 of the package substrate 100 by a predetermined distance L2. The predetermined distance L2 may be at least 800 μm.

The plurality of lower substrate pads 124 may be disposed in the middle region MR. The lower substrate pads 124 may be arranged in an array form in the middle region MR. For example, the middle region MR may be a region enclosed by lines connecting outermost points of the plurality of lower substrate pads 124 arranged in the array form to have a rectangular shape as shown in FIG. 3, and the edge region ER may be the region between the middle region MR and the side surfaces S11, S12, S13, and S14 of the package substrate 100. A data signal, a power signal, or a ground signal may be transmitted through the lower substrate pads 124. A ground substrate pad among the lower substrate pads 124 may be electrically connected to a ground wiring 126 among the wirings. Accordingly, the ground signal may be transmitted through the ground substrate pad.

As illustrated in FIGS. 3 and 4, the package substrate 100 may include a reference mark 130 that is disposed at a first corner portion adjacent to a first corner C11 of the package substrate 100 within the edge region ER on the lower surface 114. The first corner portion of the package substrate 100 may be an area in the vicinity of the first corner C11. For example, the first corner portion may be an area of the edge region ER within a distance from the first corner C11 of the package substrate 100, and the distance may be the same as a distance between the first corner C11 and the closest lower substrate pads 124 to the first corner C11 among the plurality of lower substrate pads 124 formed in the middle region MR. The reference mark 130 may be provided as a fiducial mark that provides a reference for direction or position confirmation during a package manufacturing process. The reference mark 130 may be arranged adjacent to one corner of the package substrate 100, which has a rectangular shape when viewed in plan view.

The reference mark 130 may include the same material as the lower substrate pads 124. The reference mark 130 and the lower substrate pads 124 may be formed by the same process. The reference mark 130 may be a portion of the fourth wiring 120d exposed by the lower protective layer 110e. The reference mark 130 may be a dummy pad that is electrically insulated from the wirings.

For example, the lower substrate pad 124 may have a first diameter D1, and the reference mark 130 may have a second diameter D2. The second diameter may be the same as or different from the first diameter. The first diameter and the second diameter may be within a range of 300 μm to 600 μm.

In example embodiments, at least one barrier 150 may protrude from the lower surface 114 of the package substrate 100. The at least one barrier 150 may be disposed between the first corner C11 and the reference mark 130, e.g., in a plan view. The at least one barrier 150 may extend, e.g., horizontally, between the first corner C11 and the reference mark 130 to surround at least a portion of the reference mark 130. The at least one barrier 150 may have a bent shape (e.g., L-shape) to surround the at least a portion of the reference mark 130. For example, the at least one barrier 150 may include a first barrier 152 extending lengthwise in the first corner portion in a first direction (X direction) and a second barrier 154 extending lengthwise from one end portion of the first barrier 152 in a second direction different from the first direction. The second direction may be perpendicular to the first direction.

The at least one barrier 150 may have a predetermined height H from the lower surface 114 of the package substrate 100, e.g., downwards in a vertical direction. The predetermined height H may be within a range of 5 μm to 20 μm. The at least one barrier 150 may have a first width W1 and a first length L1. The first width W1 may be within a range of 50 μm to 200 μm, and the first length L1 may be within a range of 50 μm to 600 μm. The at least one barrier 150 may be spaced apart from the first side portion/surface S11 of the package substrate 100 by a predetermined distance G. The predetermined distance G may be 200 μm or less.

For example, the at least one barrier 150 may include the same material as the lower protective layer 110e. The at least one barrier 150 may include solder resist.

As illustrated in FIGS. 1 and 2, in example embodiments, the semiconductor chip 200 may be attached to the upper surface 112 of the package substrate 100 using an adhesive film 220. The semiconductor chip 200 may be attached to the package substrate 100 using the adhesive film 220 such as a die attach film (DAF) by a die attach process. For example, a thickness of the adhesive film 220 may be within a range of 10 μm to 60 μm.

The semiconductor chip 200 may be disposed such that a second surface (inactive surface 204, which is opposite to a first surface (active surface) 202 on which chip pads 210 are formed, faces the package substrate 100. The semiconductor chip 200 may be stacked on the package substrate 100 such that the first surface 202 on which the chip pads 210 are formed faces upward.

The semiconductor chip may be a logic chip including logic circuits. The logic chip may be a controller that controls memory chips. The semiconductor chip may be a processor chip such as ASIC or an application processor AP as a host such as CPU, GPU, or SOC.

Alternatively, the semiconductor chip may include or may be a memory chip including memory circuits. For example, the semiconductor chip may include volatile memory devices such as SRAM devices or DRAM devices, and non-volatile memory devices such as flash memory devices, PRAM devices, MRAM devices or RRAM devices.

In these embodiments, one semiconductor chip is disposed on the package substrate 100, but the present inventive concept is not limited thereto, and for example, a plurality of semiconductor chips may be sequentially stacked on a package region of the package substrate.

The semiconductor chip 200 may be electrically connected to the package substrate 100 through bonding wires 230 that serve as the conductive connection members. The chip pads 210 of the semiconductor chip 200 may be electrically connected to the upper substrate pads 122 on the upper surface 112 of the package substrate 100 by the bonding wires 230.

In another embodiment, the semiconductor chip 200 may be mounted on the package substrate 100 using a flip chip bonding method. For example, the semiconductor chip 200 may be mounted on the package substrate 100 using conductive bumps. The semiconductor chip 200 may be mounted on the package substrate 100 such that the active surface on which the chip pads 210 are formed, e.g., the first surface 202, faces the package substrate 100.

In this case, the conductive bumps may include micro bumps (uBump). The conductive bumps may be formed on the chip pads 210, and the conductive bumps may be interposed between the chip pads 210 of the semiconductor chip 200 and the upper substrate pads 122 of the package substrate 100. For example, the conductive bumps may include or may be solder bumps and/or pillar bumps.

The sealing member 240 may be provided on the package substrate 100 to cover the semiconductor chip 200. For example, the sealing member 240 may include an epoxy mold compound (EMC). The sealing member 240 may include UV resin, polyurethane resin, silicone resin, silica filler, etc.

In example embodiments, the electromagnetic shielding member 400 may be provided on an upper surface and side surfaces of the unit package UP. The electromagnetic shielding member 400 may cover the side surface of the package substrate 100 and an upper surface and side surfaces of the sealing member 240. The electromagnetic shielding member 400 may include a conductive material. The electromagnetic shielding member 400 may include a plurality of stacked metal layers. For example, the electromagnetic shielding member 400 may be formed by a coating process, a spray process, a plating process, a deposition process, etc. The conductive material may include or may be metal such as copper, silver, stainless steel, etc. For example, the electromagnetic shielding member 400 may include a first metal layer, a second metal layer, and a third metal layer sequentially stacked. The first metal layer and the third metal layer may include stainless steel, and the second metal layer may include copper. The electromagnetic shielding member 400 may have a thickness of several to tens of micrometers.

A bottom surface of the unit package UP, e.g., the lower surface 114 of the package substrate 100 may be exposed by a lower end portion of the electromagnetic shielding member 400. When the electromagnetic shielding member 400 is formed, a portion of the electromagnetic shielding material may penetrate onto the lower protective layer 110e of the unit package UP and move toward the reference mark 130 at the first corner portion. For example, the electromagnetic shielding material may be formed onto a bottom surface of the lower protective layer 110e from an edge/corner of the lower protective layer 110e toward the reference mark 130. At this time, the barrier 150 may prevent the portion of the electromagnetic shielding member 400 from covering the reference mark 130.

Additionally, the electromagnetic shielding member 400 may contact a portion of the ground wiring 126 that is exposed from the side surface S11 or S12 of the package substrate 100. Accordingly, the electromagnetic shielding member 400 may be electrically connected to the ground substrate pad through the ground wiring 126.

In example embodiments, the plurality of conductive connection members 300 may be disposed on the bottom surface of the unit package UP that is exposed by the lower end portion of the electromagnetic shielding member 400, e.g., the lower surface 114 of the package substrate 100. The plurality of conductive connection members 300 may respectively disposed on the plurality of lower substrate pads 124. The plurality of conductive connection members 300 may be arranged in an array form on the middle region MR of the lower surface 114 of the package substrate 100.

For example, solder balls as the conductive connection members may be attached to the plurality of lower substrate pads 124 through a solder ball attach process. For example, the conductive connection member 300 may include tin (Sn), indium (In), bismuth (Bi), antimony (Sb), copper (Cu), silver (Ag), zinc (Zn), lead (Pb), or alloys thereof. The conductive connection members 300 may have a diameter within a range of 300 μm to 600 μm.

In example embodiments, the semiconductor package P may be mounted on the main board 20 via the plurality of conductive connection members 300. The conductive connection members 300 may be respectively disposed on the plurality of pads 24. For example, the plurality of pads 24 may have a non-solder mask defined (NSMD) type pad structure. A diameter of each of the plurality of pads 24 may be smaller than a diameter of the opening of the protective layer 22 that exposes each of the pads 24. For example, the pads 24 may be formed to be exposed through the openings of the protective layer 22.

As mentioned above, the electronic device 10 may include the main board 20 and the semiconductor package 100 disposed/mounted on the main board 20 via the plurality of conductive connection members 300. The semiconductor package 100 may include the unit package UP and the electromagnetic shielding member 400 covering the upper surface and the side surface of the unit package UP. The unit package UP may include the package substrate 100 having the lower substrate pads 124 disposed in the middle region MR on the lower surface 114 and the reference mark 130 disposed at the first corner portion adjacent to the first corner C11 within the edge region ER surrounding the middle region MR and at least one barrier 150 disposed on the lower surface 114 of the package substrate 100 between the reference mark 130 and the first corner C11.

When the electromagnetic shielding member 400 is formed, a backspill defect where a portion of the electromagnetic shielding material penetrates or is formed onto the lower surface 114 of the unit package UP to cover the reference mark 130 at the first corner portion may occur. At this time, the at least one barrier 150 may block the portion of the electromagnetic shielding member 400 from moving to the reference mark 130 to thereby prevent the backspill defect. For example, the barrier 150 may prevent the electromagnetic shielding member 400 from being formed on the reference mark 130.

Accordingly, the position and inspection position of the package may be automatically corrected by checking the reference mark 130 during a manufacturing process such as a package mounting process after the formation process of the electromagnetic shielding member 400.

Hereinafter, a method of manufacturing the semiconductor package in FIG. 1 will be explained.

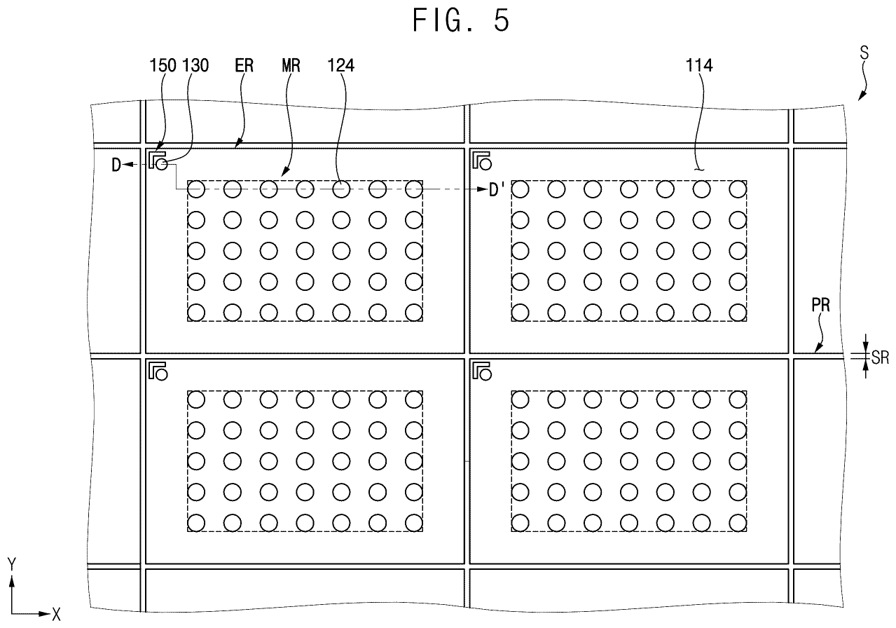

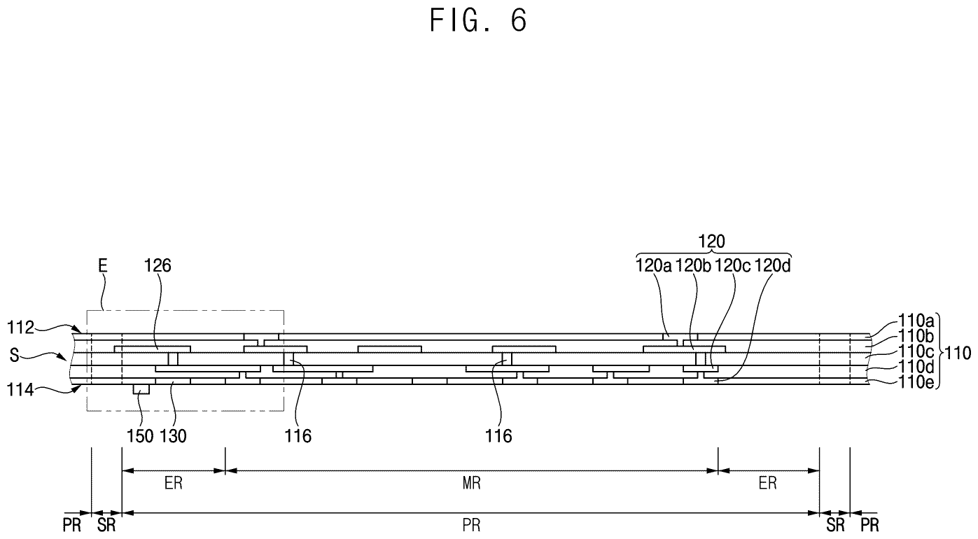

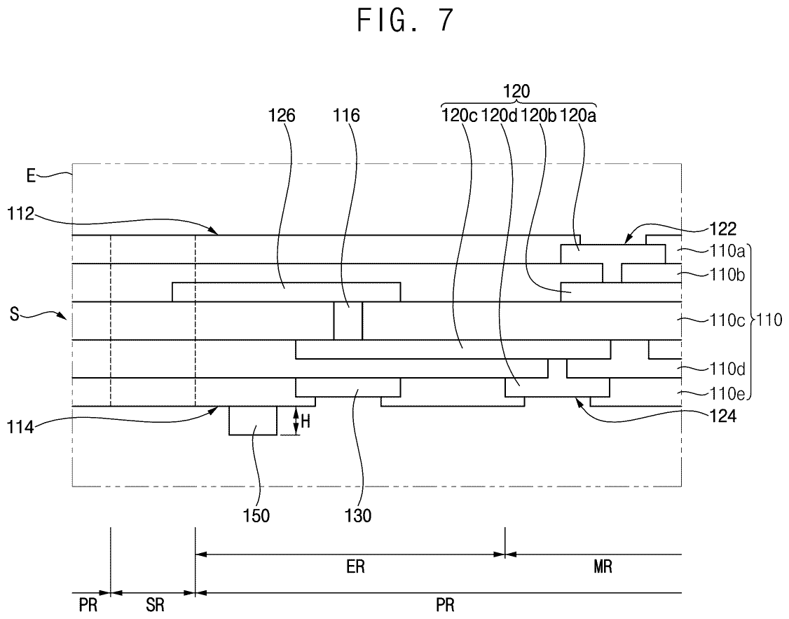

FIGS. 5 to 15 are views illustrating a method of manufacturing an electronic device in accordance with example embodiments. FIG. 5 is a plan view illustrating a strip substrate on which semiconductor chips are to be mounted. FIGS. 6, 8, 9, 10, 11, 12, 13, 14 and 15 are cross-sectional views illustrating a method of manufacturing an electronic device in accordance with example embodiments. FIG. 7 is an enlarged cross-sectional view illustrating portion ‘E’ in FIG. 6. FIG. 6 is a cross-sectional view taken along the line D-D′ in FIG. 5.

Referring to FIGS. 5 to 7, a substrate S in which package substrates are formed may be provided.

In example embodiments, the substrate S may be a multilayer circuit substrate having an upper surface 112 and a lower surface 114 opposite to each other. The substrate S may be a strip substrate for manufacturing a semiconductor strip, such as a printed circuit board (PCB). The substrate S may include or may be a printed circuit board (PCB), a flexible substrate, a tape substrate, etc. The substrate S may be a multilayer circuit board having vias and various circuits therein.

As illustrated in FIG. 5, the substrate S may include a package region PR on which a semiconductor chip is to be mounted and a scribe lane region surrounding the package region PR, e.g., a cutting region SR. As will be described later, after a plurality of semiconductor chips are respectively disposed on package regions PR of the substrate S, the substrate S may be cut along the cutting region SR dividing the package regions PR to be individualized into package substrates. For example, tens to hundreds of semiconductor chips may be arranged in a matrix form on the substrate S.

As illustrated in FIG. 6, the substrate S may include a plurality of stacked insulating layers 110 and wirings 120a, 120b, 120c respectively provided in the insulating layers. Additionally, the substrate S may include a plurality of upper substrate pads 122 and a plurality of lower substrate pads 124.

For example, the substrate S may include first to fifth insulating layers 110a, 110b, 110c, 110d, 100e sequentially stacked. The first insulating layer 110a may be an upper cover insulating layer, the second insulating layer 110b may be an upper insulating layer, the third insulating layer 110c may be a core layer, the fourth insulating layer 110d may be a lower insulating layer, and the fifth insulating layer 110e may be a lower cover insulating layer.

For example, the insulating layer may include an insulating material having a thermosetting resin such as epoxy resin or a thermoplastic resin such as polyimide. The insulating layer may include a resin impregnated into a core material such as organic fiber (glass fiber), for example, prepreg, FR-4, or BT (Bismaleimide Triazine). Additionally or in certain embodiments, the insulating layer may include a polymer, a dielectric layer, a silicon oxide layer, a silicon nitride layer, a silicon oxynitride layer, etc.

A second wiring 120b may be formed on an upper surface of the third insulating layer 110c. The second insulating layer 110b may be formed on the upper surface of the third insulating layer 110c to cover the second wiring 120b. A first wiring 120a may be formed on an upper surface of the second insulating layer 110b, and may be electrically connected to the second wiring 120b through an opening formed in the second insulating layer 110b.

A third wiring 120c may be formed on a lower surface of the third insulating layer 110c. The fourth insulating layer 110d may be formed on the lower surface of the third insulating layer 110c to cover the third wiring 120c. A fourth wiring 120d may be formed on a lower surface of the fourth insulating layer 110d, and may be electrically connected to the third wiring 120c through an opening formed in the fourth insulating layer 110d.

The first to fourth wirings 120a, 120b, 120c and 120d may be referred to as a first to fourth circuit layers stacked in a thickness direction from the upper surface 112 to the lower surface 114 of the substrate S. For example, the wiring may include metal materials such as copper, aluminum, etc. It will be understood that the arrangements and numbers of the insulating layers and the wirings are illustrative and the inventive concept is not limited thereto.

A conductive through via 116 may penetrate the third insulating layer 110c as the core layer and electrically connect the second wiring 120b and the third wiring 120c to each other. The first wiring 120a may be exposed from the upper surface 112 of the substrate S. The fourth wiring 120d may be exposed from the lower surface 114 of the substrate S.

The first insulating layer 110a as an upper protective layer may be formed on the upper surface 112 of the substrate S, and may expose at least a portion of the first wiring 120a. For example, the first insulating layer 110a may be formed at a top of the package substrate 100, and an upper surface of the first insulating layer 110a may form the upper surface 112 of the package substrate 100. The exposed portion of the first wiring 120a may be provided as the upper substrate pad 122. The fifth insulating layer 110e as a lower protective layer may be provided on the lower surface 114 of the package substrate 100, and may expose at least a portion of the fourth wiring 120d. For example, the fifth insulating layer 110e may be formed at a bottom of the package substrate 100, and a lower surface of the fifth insulting layer 110e may form the lower surface 114 of the package substrate 100. The exposed portion of the fourth wiring 120d may be provided as the lower substrate pad 124. The upper insulating layer 110a and the lower insulating layer 110e may separate the circuit patterns of the substrate S from the external environment to prevent contamination and electrically insulate the wirings of the circuit patterns from each other. For example, the upper insulating layer and the lower insulating layer may include a photosensitive resin such as photo epoxy or a photosensitive polymer such as photo solder resist (PSR).

In example embodiments, the package region PR of the substrate S may include a middle region MR and an edge region ER surrounding the middle region MR. The middle region MR may be spaced apart from one side portion of the substrate S, e.g., the cutting region SR by a predetermined distance. The predetermined distance may be at least 800 μm.

The plurality of lower substrate pads 124 may be disposed in the middle region MR of the package region PR. The lower substrate pads 124 may be arranged in an array form in the middle region MR. A data signal, a power signal, or a ground signal may be transmitted through the lower substrate pads 124. A ground substrate pad among the lower substrate pads 124 may be electrically connected to a ground wiring 126 among the wirings. Accordingly, the ground signal may be transmitted through the ground substrate pad.

As illustrated in FIGS. 5 and 7, the substrate S may include a reference mark 130 that is disposed at a first corner portion adjacent to the a first corner of the package region PR within the edge region ER on the lower surface 114 of the substrate S. The reference mark 130 may be provided as a fiducial mark that provides a reference for direction or position confirmation during a package manufacturing process. The reference mark 130 may be arranged adjacent to one corner of the package region PR, which has a rectangular shape when viewed in plan view.

The reference mark 130 may include the same material as the lower substrate pads 124. The reference mark 130 and the lower substrate pads 124 may be formed by the same process. The reference mark 130 may be a portion of the fourth wiring 120d exposed by the lower protective layer 110e. The reference mark 130 may be a dummy pad that is electrically insulated from the wirings.

For example, the lower substrate pad 124 may have a first diameter, and the reference mark 130 may have a second diameter. The second diameter may be the same as or different from the first diameter. The first diameter and the second diameter may be within a range of 300 μm to 600 μm.

In example embodiments, at least one barrier 150 may be formed to protrude, e.g., downwards, from the lower surface 114 of the substrate S. The at least one barrier 150 may be disposed between the first corner and the reference mark 130 at the first corner portion. The at least one barrier 150 may extend between the first corner and the reference mark 130 and/or at the first corner region to surround at least a portion of the reference mark 130. The at least one barrier 150 may have a bent shape to surround the at least a portion of the reference mark 130.

The at least one barrier 150 may have a predetermined height H from the lower surface 114 of the substrate S, e.g., downwards in a vertical direction. The predetermined height H may be within a range of 5 μm to 20 μm. The at least one barrier 150 may have a first width W1 and a first length L1. The first width W1 may be within a range of 50 μm to 200 μm, and the first length L1 may be within a range of 50 μm to 600 μm.

For example, a first photosensitive insulating layer and a second photosensitive insulating layer may be formed on the fourth insulating layer 110d of the substrate S, and an exposure process and a development process may be performed on the second photosensitive insulating layer to form the at least one barrier 150. Then, an exposure process and a development process may be performed on the first photosensitive insulating layer to form the lower protective layer 110e. The at least one barrier 150 may include the same material as the lower protective layer 110e. The at least one barrier 150 may include solder resist.

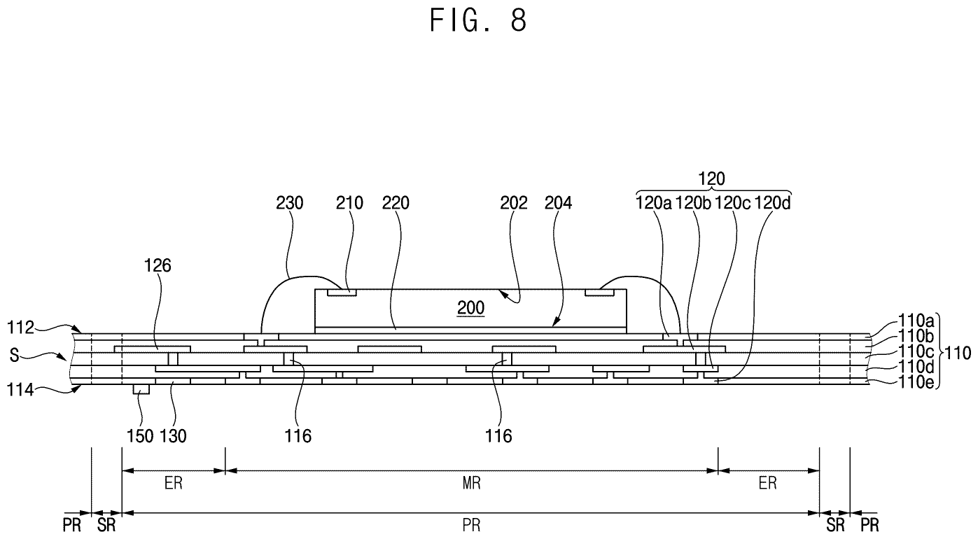

Referring to FIG. 8, at least one semiconductor chip 200 may be mounted on the substrate S.

In example embodiments, the semiconductor chip 200 may be attached to the package region PR of the substrate S using an adhesive film 220. The semiconductor chip 200 may be attached to the substrate S using the adhesive film 220 such as a die attach film (DAF) by a die attach process. For example, a thickness of the adhesive film 220 may be within a range of 10 μm to 60 μm.

The semiconductor chip 200 may be disposed such that a second surface (inactive surface 204, which is opposite to a first surface (active surface) 202 on which chip pads 210 are formed, faces the substrate S. The semiconductor chip 200 may be stacked on the package substrate 100 such that the first surface 202 on which the chip pads 210 are formed faces upwards.

The semiconductor chip may be a logic chip including logic circuits. The logic chip may be a controller that controls memory chips. The semiconductor chip may be a processor chip such as ASIC or an application processor AP as a host such as CPU, GPU, or SOC.

Alternatively, the semiconductor chip may include a memory chip including memory circuits. For example, the semiconductor chip may include volatile memory devices such as SRAM devices or DRAM devices, and non-volatile memory devices such as flash memory devices, PRAM devices, MRAM devices or RRAM devices.

In these embodiments, one semiconductor chip is disposed on the package substrate 100, but the present inventive concept is not limited thereto, and for example, a plurality of semiconductor chips may be sequentially stacked on the package region of the substrate.

Then, the semiconductor chip 200 may be electrically connected to the substrate S through bonding wires 230 that serve as conductive connection members.

In example embodiments, a wire bonding process may be performed to connect the chip pads 210 of the semiconductor chip 200 to the upper substrate pads 122 on the upper surface 112 of the substrate S using the bonding wires 230.

In another embodiment, the semiconductor chip 200 may be mounted on the substrate S using a flip chip bonding method. The semiconductor chip 200 may be mounted on the substrate S using conductive bumps. The semiconductor chip 200 may be mounted on the substrate S such that the active surface on which the chip pads 210 are formed, that is, the first surface 202, faces the substrate S.

In this case, the conductive bumps may include or may be micro bumps (uBump). The conductive bumps may be formed on the chip pads 210, and the conductive bumps may be interposed between the chip pads 210 of the semiconductor chip 200 and the upper substrate pads 122 of the substrate S. For example, the conductive bumps may include or may be solder bumps and/or pillar bumps.

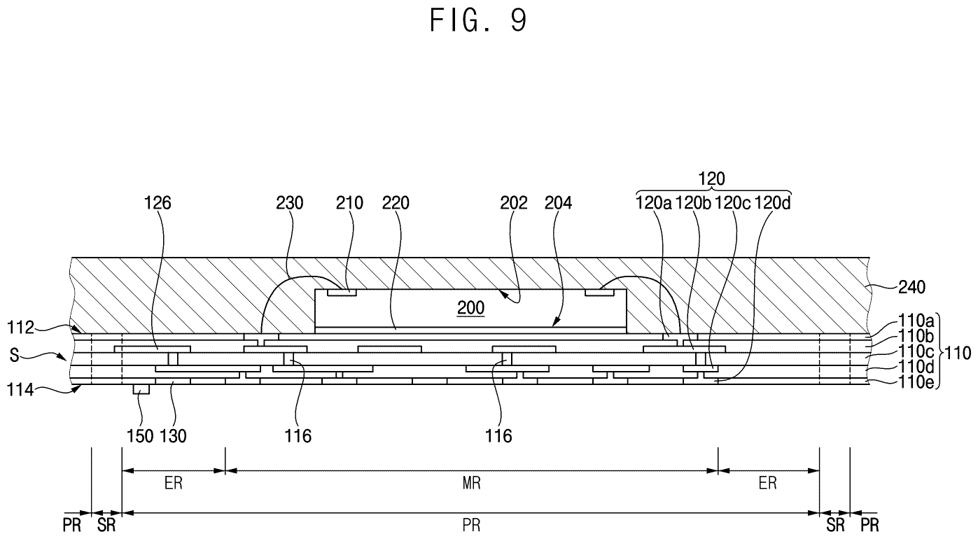

Referring to FIG. 9, a sealing member 240 may be formed on the substrate S to cover the semiconductor chip 200.

For example, the sealing member 240 may include an epoxy mold compound (EMC). The sealing member 240 may include UV resin, polyurethane resin, silicone resin, silica filler, etc.

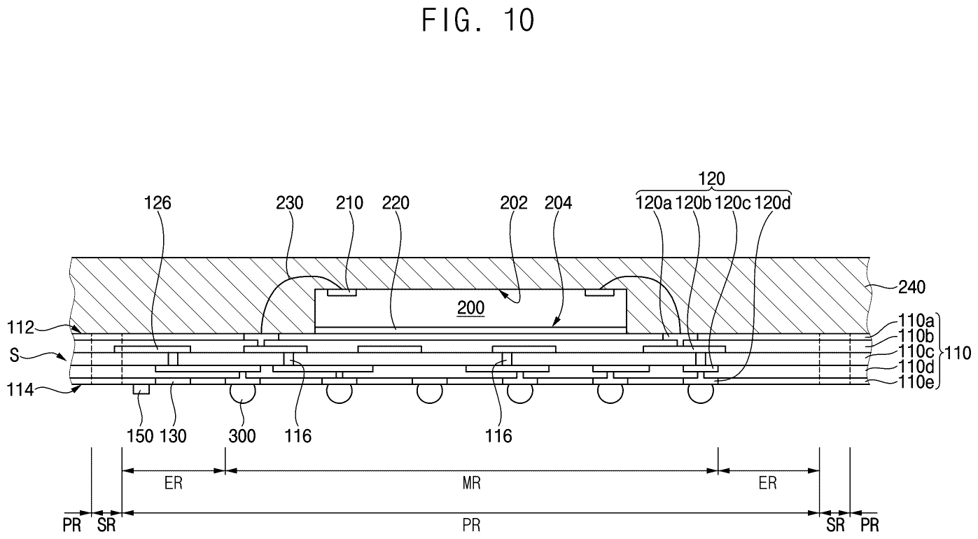

Referring to FIG. 10, a plurality of conductive connection members 300 may be formed on the plurality of lower substrate pads 124 on the lower surface 114 of the substrate S. An under bump metallurgy (UBM) layer may be formed on the lower substrate pads 124 for bonding to the conductive connection members 300.

In example embodiments, solder balls serving as the conductive connection members may be attached to the plurality of lower substrate pads 124 by a solder ball attach process. For example, a solder ball attachment apparatus may include a body and a solder ball holding portion. The body may include an internal space in communication with an external vacuum forming device, and the solder ball holding portion may include a plurality of suction pockets in communication with the internal space and capable of selectively adsorbing solder balls, respectively. A vacuum may be provided to the suction pockets to adsorb the solder balls, and the vacuum may be removed from the suction pockets to attach the solder balls to the lower substrate pads 124 of the substrate S, respectively.

The plurality of conductive connection members 300 may be arranged in an array form on the middle region MR of the lower surface 114 of the package substrate 100. The conductive connection members 300 may have a diameter within a range of 300 μm to 600 μm.

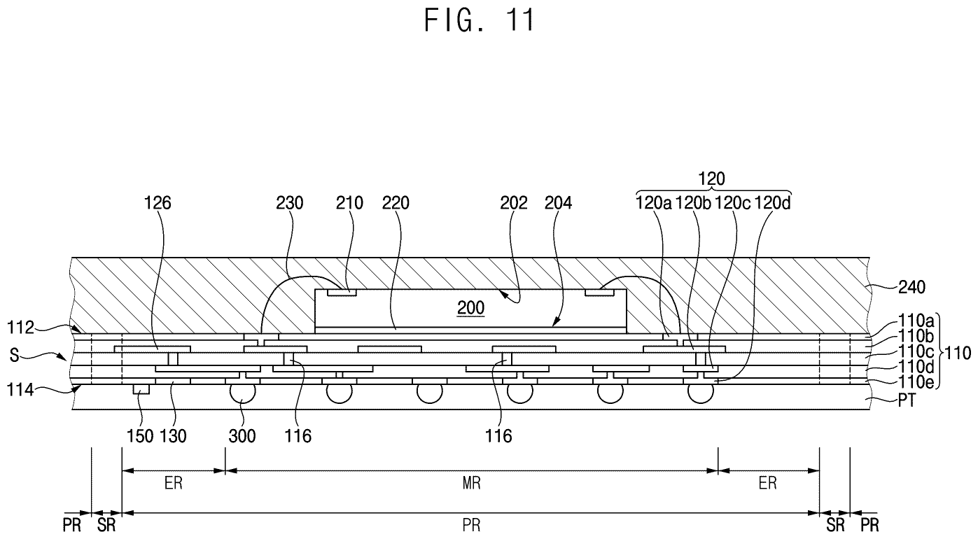

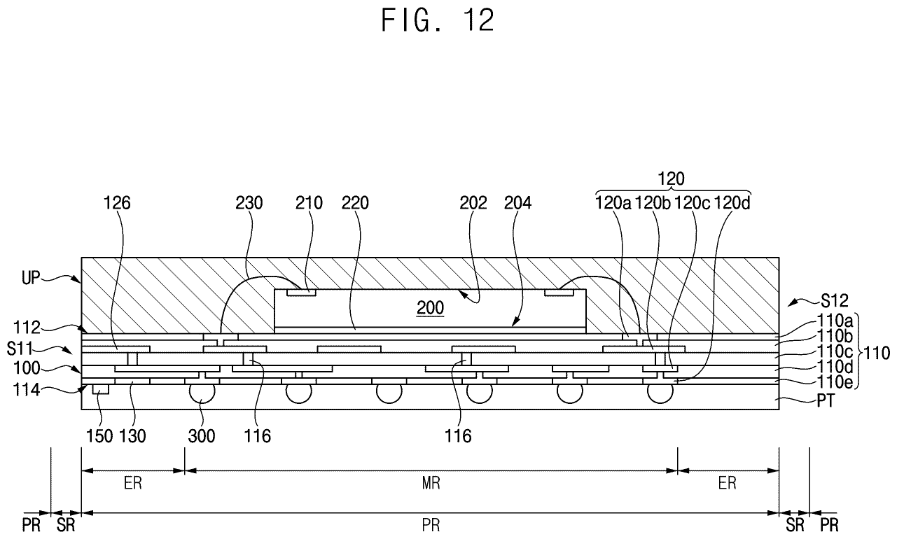

Referring to FIGS. 11 and 12, a protective tape PT may be formed on the lower surface 114 of the substrate S, and the substrate S may be cut along the cutting region SR to form an individual unit package UP.

As illustrated in FIG. 11, the protective tape PT may be attached to the lower protective layer 110e of the substrate S. The protective tape PT may have a thickness such that the protective tape is able to cover the plurality of conductive connection members 300. The protective tape PT may include or may be a UV curable dicing tape. The protective tape PT may be attached to the lower protective layer 110e of the substrate S by a lamination process. The protective tape PT may cover the at least one barrier 150 on the lower protective layer 110e. As will be described later, the protective tape PT may prevent an electromagnetic shielding material from infiltrating the lower surface 114 of the substrate S during a sputtering process of forming an electromagnetic shielding member. For example, the protective tape PT may be helpful to make the electromagnetic shielding material not to be attached on the lower surface 114 of the substrate S during the sputtering process of forming an electromagnetic shielding member 400.

As illustrated in FIG. 12, the cutting region SR of the substrate S may be removed using a sawing apparatus including as a blade. Thus, the substrate S may be separated into individual unit packages UP. At this time, the protective tape PT may be also cut, and a portion of the ground wire 126 may be exposed from a side portion S11 of a package substrate 100.

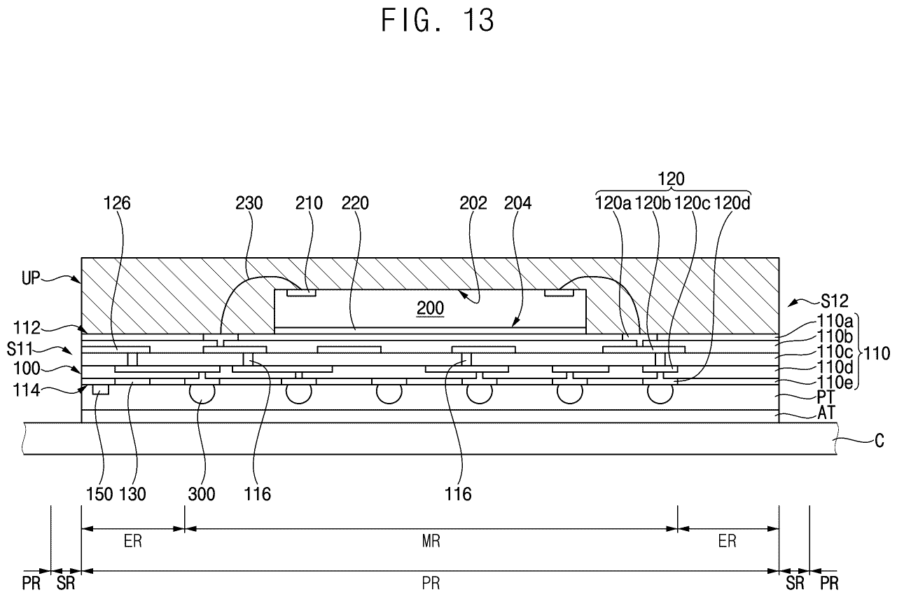

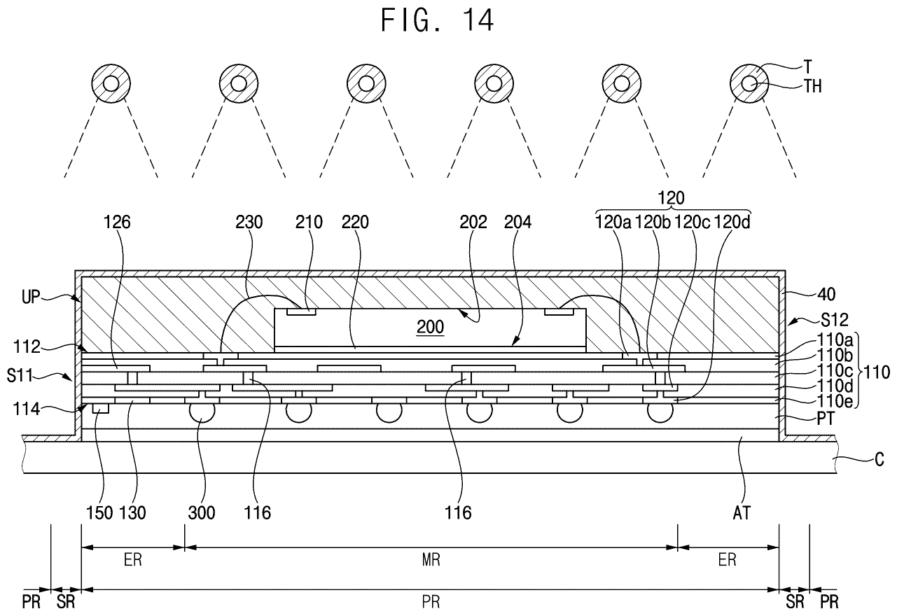

Referring to FIGS. 13 and 14, the unit package UP of FIG. 12 may be attached to a carrier substrate C, and a metal layer may be deposited on a top surface and side surfaces of the unit package UP to form an electromagnetic shielding layer 40.

As illustrated in FIG. 13, the unit package UP of FIG. 12 may be attached to the carrier substrate C using an adhesive tape AT. Accordingly, the unit package UP may be supported on the carrier substrate C. An adhesive force between the adhesive tape AT and the protective tape PT may be greater than an adhesive force between the protective tape PT and a lower surface of the unit package P, e.g., between the protective tape PT and the lower protective layer 110e.

As illustrated in FIG. 14, the electromagnetic shielding layer 40 may be formed by stacking a metal layer on the top and side surfaces of the unit package UP. The electromagnetic shielding layer 40 may include a conductive material. The conductive material may include metal such as copper, silver, stainless steel, etc. For example, the electromagnetic shielding layer 40 may be formed by a coating process, a spray process, a plating process, a deposition process, etc.

For example, the unit package UP supported on the carrier substrate C may be loaded into a sputtering chamber, and particles sputtered from a target T placed on a target holder TH may be deposited on a surface of the unit package UP. The sputtering chamber may include a plurality of targets T. The plurality of targets T may include a first group of targets and a second group of targets. Particles sputtered from the first group of targets may be deposited on the unit package UP to form a first metal layer. Particles sputtered from the second group of targets may be deposited on the unit package UP to form a second metal layer. The electromagnetic shielding layer 40 may include the first metal layer, the second metal layer, and a third metal layer sequentially stacked. The first metal layer and the third metal layer may include stainless steel, and the second metal layer may include copper.

When the electromagnetic shielding layer 40 is deposited, a portion of the electromagnetic shielding layer 40 may penetrate between the protective tape PT and the lower protective layer 110e of the unit package UP to move to or cover the reference mark 130 at the first corner portion adjacent to the first corner. At this time, the barrier 150 may prevent the portion of the electromagnetic shielding layer 40 from covering the reference mark 130. For example, the barrier 150 may block the electromagnetic shielding material such that the electromagnetic shielding material does not move toward the reference mark 130. Accordingly, visibility of the reference mark 130 may be secured in subsequent manufacturing processes.

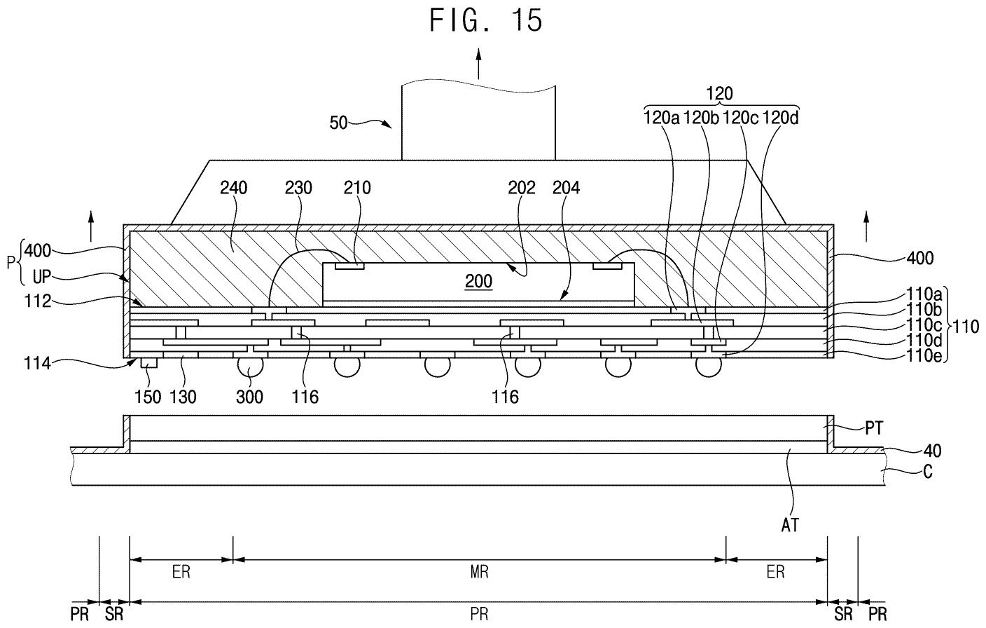

Referring to FIG. 15, the protective tape PT may be separated from the lower surface of the unit package UP to form a semiconductor package P including an electromagnetic shielding member 400 that covers the side and upper surfaces of the unit package UP.

After a picker 50 of a vacuum pickup apparatus adsorbs and hold the electromagnetic shielding member/layer 400, the picker may move upward such that the protective tape PT is separated from the lower surface of the unit package UP. Accordingly, a portion of the electromagnetic shielding layer 40 may be separated to form the electromagnetic shielding member 400, and the conductive connection members 300 on the lower surface of the unit package UP may be exposed. The picker 50 may transfer the semiconductor package P onto a stage of a mounting apparatus to perform a mounting process.

Then, as illustrated in FIG. 1, the semiconductor package P may be mounted on a main board 20 via the plurality of conductive connection members 300.

In example embodiments, the main board 20 may be a multilayer circuit board having an upper surface and a lower surface opposite to each other. For example, the main board 20 may be a printed circuit board (PCB). The printed circuit board may be a multilayer circuit board having vias and various circuits therein.

The main board 20 may include a plurality of pads 24 on the upper surface thereof and a protective layer 22 having openings that expose the plurality of pads 24 respectively. The plurality of pads 24 may be electrically connected to various circuit wires formed in the main board 20. The plurality of pads 24 may include a plurality of signal pads and a plurality of ground pads. The ground pads may be electrically connected to a separate ground circuit (not shown) formed in the main board 20.

The plurality of conductive connection members 300 may be disposed on the plurality of pads 24. For example, the plurality of pads 24 may have a non-solder mask defined (NSMD) type pad structure. A diameter of each of the plurality of pads 24 may be smaller than a diameter of the opening of the protective layer 22 that exposes each of the pads 24. For example, the pads 24 may be formed to be exposed through the openings of the protective layer 22. For example, along perimeters of the pads 24, a lower layer or substrate on which the pads 24 are formed may be exposed through the openings of the protective layer 22.

After the semiconductor package P having the plurality of conductive connection members 300 formed thereon is placed on the main board 20, a reflow process may be performed to bond the plurality of conductive connection members 300 to the plurality of pads 24 on the main board 20. The plurality of conductive connection members 300 may be bonded to the plurality of pads 24, to complete the electronic device 10 of FIG. 1.

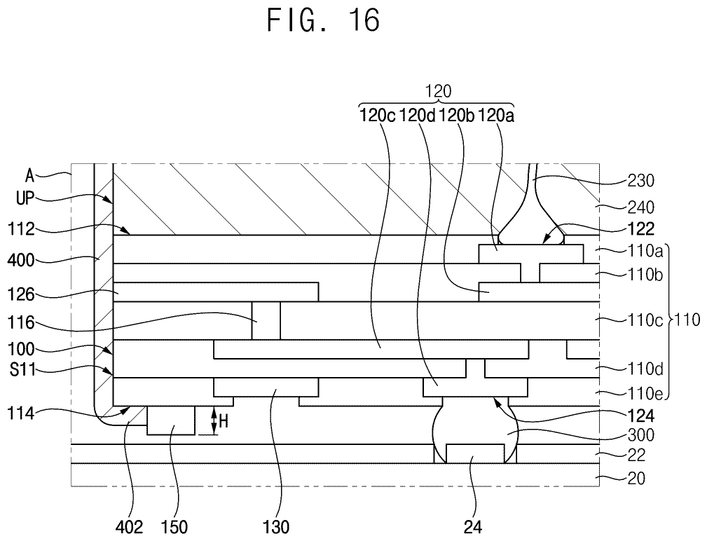

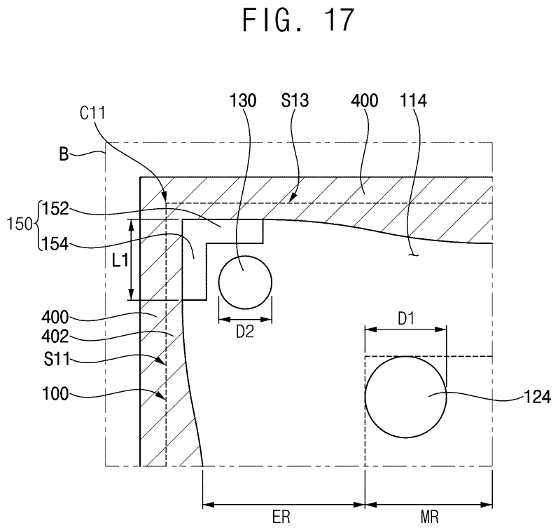

FIG. 16 is an enlarged cross-sectional view illustrating the electromagnetic shielding member that has penetrated onto the lower surface of the semiconductor package in portion ‘A’ of FIG. 1. FIG. 17 is a bottom view illustrating the lower surface of the semiconductor package of FIG. 16.

Referring to FIGS. 16 and 17, when the processes described with reference to FIG. 14 are performed to deposit the electromagnetic shielding layer, a portion of the electromagnetic shielding layer may penetrate onto the lower surface 114 of the unit package UP. At this time, the at least one barrier 150 may block the portion of the electromagnetic shielding film from moving to the reference mark 130. Then, the processes described with reference to FIG. 15 may be performed to form the semiconductor package P including the electromagnetic shielding member 400 that covers the top and side surfaces of the unit package UP.

A portion 402 of the electromagnetic shielding member 400 may be formed in the edge region ER on the lower surface 114 of the package substrate 100 along side portions/surfaces S11 and S13 of the package substrate 100. The portion 402 of the electromagnetic shielding member 400 may contact the barrier 150 at the first corner portion adjacent to the first corner C11 within the edge region ER such that entry into/over the reference mark 130 can be blocked. The barrier 150 may prevent the portion 402 of the electromagnetic shielding member 400 from covering the reference mark 130.

The semiconductor package of the electronic device may include semiconductor devices such as logic devices or memory devices. The semiconductor package may include logic devices such as central processing units (CPUs), main processing units (MPUs), or application processors (APs), or the like, and/or volatile memory devices such as DRAM devices, HBM devices, or non-volatile memory devices such as flash memory devices, PRAM devices, MRAM devices, ReRAM devices, or the like.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of invention as defined in the claims.

What is claimed is:

1. A semiconductor package, comprising:
a package substrate having substrate pads disposed in a middle region and a reference mark disposed at a first corner portion adjacent to a first corner within an edge region surrounding the middle region on a lower surface of the package substrate;
at least one semiconductor chip mounted on an upper surface of the package substrate;
a sealing member covering the at least one semiconductor chip on the package substrate;
an electromagnetic shielding member covering a side surface of the package substrate and an upper surface and a side surface of the sealing member; and
at least one barrier protruding downwards from the lower surface of the package substrate and is disposed between the first corner and the reference mark.

2. The semiconductor package of claim 1, wherein the at least one barrier includes:
a first barrier extending in a first direction; and
a second barrier extending from one end portion of the first barrier in a second direction different from the first direction.

3. The semiconductor package of claim 1, wherein the at least one barrier has a first height from the lower surface of the package substrate, and the first height is within a range of 5 μm to 20 μm.

4. The semiconductor package of claim 1, wherein the at least one barrier has a first width and a first length, the first width being within a range of 50 μm to 200 μm, and the first length being within a range of 50 μm to 600 μm.

5. The semiconductor package of claim 1, wherein the at least one barrier is spaced apart from a side of the package substrate by a first distance, and the first distance is 300 μm or less.

6. The semiconductor package of claim 1, wherein the middle region is spaced apart from a side surface of the package substrate by a second distance, and the second distance is at least 800 μm.

7. The semiconductor package of claim 1, wherein the at least one barrier comprises solder resist.

8. The semiconductor package of claim 1, wherein the reference mark includes the same material as the substrate pads.

9. The semiconductor package of claim 1, wherein the reference mark has a first diameter, and the first diameter is within a range of 300 μm to 600 μm.

10. The semiconductor package of claim 1, wherein the package substrate includes a ground wiring therein, and a portion of the ground wiring is exposed from a side surface of the package substrate and contacts the electromagnetic shielding member.

11. A semiconductor package, comprising:
a package substrate including a middle region and an edge region surrounding the middle region, the package substrate including a reference mark that is disposed at a first corner portion adjacent to a first corner within the edge region on a lower surface of the package substrate to provide a reference for orientation or positioning during a manufacturing process;
at least one semiconductor chip mounted on an upper surface of the package substrate;
a sealing member covering the at least one semiconductor chip on the package substrate;
an electromagnetic shielding member covering a side surface of the package substrate and an upper surface and a side surface of the sealing member; and
at least one barrier protruding downwards on the lower surface of the package substrate and extending between the first corner and the reference mark to surround at least a portion of the reference mark.

12. The semiconductor package of claim 11, wherein the package substrate includes substrate pads arranged in the middle region.

13. The semiconductor package of claim 11, wherein the at least one barrier includes:
a first barrier extending in a first direction; and
a second barrier extending from one end portion of the first barrier in a second direction different from the first direction.

14. The semiconductor package of claim 11, wherein the at least one barrier has a first height from the lower surface of the package substrate, and the first height is within a range of 5 μm to 20 μm.

15. The semiconductor package of claim 11, wherein the at least one barrier has a first width and a first length, the first width being within a range of 50 μm to 200 μm, and the first length being within a range of 50 μm to 600 μm.

16. The semiconductor package of claim 11, wherein the at least one barrier is spaced apart from a side surface of the package substrate by a first distance, and the first distance is 300 μm or less.

17. The semiconductor package of claim 11, wherein the at least one barrier comprises solder resist.

18. The semiconductor package of claim 11, wherein the reference mark includes the same material as substrate pads on the lower surface of the package substrate.

19. The semiconductor package of claim 11, wherein the package substrate includes a ground wiring therein, and a portion of the ground wiring is exposed from a side surface of the package substrate and contacts the electromagnetic shielding member.

20. An electronic device, comprising:
a main board;
a semiconductor package disposed on the main board and mounted via a plurality of conductive connection members; and
an electromagnetic shielding member covering an upper surface and a side surface of the semiconductor package,
wherein the semiconductor package includes:
a package substrate having a middle region and an edge region surrounding the middle region, the package substrate including a reference mark that is disposed at a first corner portion adjacent to a first corner within the edge region on a lower surface of the package substrate; and
at least one barrier protruding downwards on the lower surface of the package substrate and disposed between the first corner and the reference mark.
